(19) United States
(12) Patent Application Publication
(10) Pub. No.: US 2007/0181933 A1
(43) Pub. Date: Aug. 9, 2007

(54) NON-VOLATILE MEMORY ELECTRONIC DEVICE

(75) Inventors: Giorgio Servalli, Ciserano (IT); Gianfranco Capetti, Sorisole (IT); Pietro Cantu, Lecco (IT)

Correspondence Address: SEED INTELLECTUAL PROPERTY LAW GROUP PLLC, 701 FIFTH AVENUE, SUITE 5400, SEATTLE, WA, 98104-7092, US

(73) Assignee: STMICROELECTRONICS S.R.I., Agrate Brianza (IT)

(21) Appl. No.: 11/617,472

(22) Filed: Dec. 28, 2006

(30) Foreign Application Priority Data
Dec. 30, 2005 (EP) 05425940.3

(51) Int. Cl. H01L 29/76

(52) U.S. Cl. 257/314

(57) ABSTRACT

A non-volatile memory device integrated on semiconductor substrate and having a matrix of non-volatile memory cells organized in rows, called word lines, and columns, called bit lines, the device including a plurality of active areas formed on the semiconductor substrate equidistant from each other, and having at least a first and a second group of active areas; the non-volatile memory cells integrated in the first group of active areas, each non-volatile memory cell having a source region, a drain region, and a floating gate electrode coupled to a control gate electrode, at least one group of the memory cells sharing a common source region integrated on the semiconductor substrate; and a contact region integrated in the second group of active areas and provided with at least one common source contact of the common source region.

### FIELD OF APPLICATION

### BACKGROUND OF THE INVENTION

1. Field of the Invention

The present disclosure relates to a non-volatile memory electronic device and, more particularly, to a non-volatile memory electronic device having structural characteristics that simplify the lithographic definition of the critical masks in the matrix.

2. Description of the Related Art

Non-volatile memory electronic devices, for example of the Flash type, integrated on a semiconductor substrate include a matrix of non-volatile memory cells that are organized in rows, called word lines, and columns, called bit lines. Each single non-volatile memory cell includes a MOS transistor wherein the gate electrode, placed above the channel region, is floating, i.e., it shows a high DC impedance towards all the other terminals of the same cell and of the circuit wherein the cell is inserted.

The cell also includes a second electrode, called a control gate, that is capacitively coupled to the floating gate electrode through an intermediate dielectric layer, so called interpoly. This second electrode is driven through suitable control voltages. The other electrodes of the transistor are the usual drain and source terminals. The cells coupled to a same word line share the electric line that drives the respective control gates, while the cells coupled to a same bit line share the drain terminals.

An architecture for non-volatile memory matrixes of the NOR type is, for example, shown with reference to FIG. 1.

In particular, on a semiconductor substrate 1 a plurality of active areas 2 are realized wherein the memory cells will be formed. Groups A of active areas, wherein the active areas 2 are equidistant from each other, are separated by active areas 3 of greater dimensions with respect to the active areas 2 and more spaced from these groups A of active areas.

In particular, the active areas 2 of the group A have a same width B and adjacent active areas 2 are spaced by a same distance C. The sum of the width B and of the distance C defines the pitch of the memory matrix, conventionally indicated as pitch X. Each active area 2, 3 is surrounded by an oxide layer called field oxide.

After having formed at least one tunnel oxide layer and a first polysilicon layer on the semiconductor substrate 1, in this polysilicon layer, the floating gate electrodes of the memory cells 6 are then defined having width W along a first direction.

After having formed at least one interpoly layer and one second polysilicon layer on the whole memory matrix, the second polysilicon layer, the interpoly layer, the first polysilicon layer and the oxide layer are etched in sequence, through a photolithographic mask until the semiconductor substrate 1 is exposed and the gate electrodes of the memory cells 6 having length L are completed.

In particular, with this latter etching step, in the second polysilicon layer, word lines 4 of the matrix of memory cells 6 are defined. The portions of the word lines aligned to the floating gate electrodes form control gate electrodes of the single memory cells 6. In matrixes of memory cells with NOR architecture, groups 5 of memory cells 6 share a common source region 7. This common source region 7 is obtained by removing a portion of the oxide layer between the adjacent active areas and carrying out a dopant implantation in the semiconductor substrate 1.

To avoid excessive resistance in the common source region 7, the matrix of cells is interrupted at regular intervals (each 16 cells, or each 32 cells) by inserting a contact region 8 at the interconnection with the common source region 7. This contact region 8 is formed in correspondence with the active area 3 that has been provided with greater dimensions with respect to the active areas 2 wherein the single memory cells have been formed. In fact, to allocate the contact region 8 without electric interference problems, the source region 7 will have to provide a pad 9 widened in correspondence with this contact region 8. A source contact 8a is then formed in correspondence with the widened pad 9 for contacting the active area 3 of greater dimensions and the common source region 7.

Also the polysilicon layer forming the word lines 4 must thus provide a particular shaping to accommodate the insertion of the widened pad 9 as shown in FIG. 1.

In fact, memory devices of the NOR type with high density are generally designed with SAS architecture (Self Aligned Source) to reduce the dimension of the memory cell 6. Therefore the common source region 7 is self-aligned to the word lines 4 and thus the word lines 4 follow the profile of the widened pad 9.

After having formed drain regions of the memory cells 6 inside the active areas 2, drain contacts are formed 10 aligned to each other, while the source contact 8a is formed in correspondence with the widened pad 9.

Although this design is advantageous under several aspects, it has several drawbacks.

The continuous reduction of the dimension of the memory cells 6 and in particular the continuous reduction of the pitch of the masks to form the active areas and the floating regions prevents the formation of the contact region 8 with the same pitch X of the cells, since there is no way to insert the shaping of the wordline 4 without reducing, in a non sustainable way, the dimension of the second polysilicon layer or the distance between the contact region 8 and the polysilicon layer itself.

In consequence not only of the space dedicated to the contact region 8 that is to be increased with respect to the space of a memory cell, the regularity of the matrix pitch in correspondence with the contact region 8 is also to be interrupted.

From the lithographic point of view, this interruption of the matrix pitch is a problem, especially if, for forming the photolithographic masks to be used in the manufacturing process of the memory device, lithographic lightning techniques called Off-Axis are used that are particularly dedicated to the definition of regular matrixes formed by lines and spaces. These lightning techniques, necessary when the pitch X becomes comparable or lower than the wavelength of the radiation used to defined structures on the semiconductor substrate, show a significant degrade of their performances each time when the regularity of the structures to be defined is interrupted.

With respect to the formation of the contact region 8, two technical problems are identified:

the breakage of the periodicity of the definition of the active areas 2 complicates the possibility of proximity corrections to be applied to the masks for obtaining the desired dimensions. In particular, it is difficult to form active areas 2 adjacent to the widest active area 3 having the same dimensions as the other active areas 2 of the memory matrix,

the breakage of the periodicity generates a structure that is highly sensitive to the aberrations of the projection optical system. These distortions impact in an asymmetric way onto the control of the critical dimensions of the memory cells 6, therefore bitlines being nominally identical on mask are of different dimension on wafer, with consequences also on the dimensions of the adjacent spaces, and possible problems in filling in the field oxide region.

The technical problem underlying the present invention is that of providing a non-volatile memory electronic device, having structural characteristics that simplify the lithographic definition of the critical masks in the matrix overcoming the limits and the drawbacks still affecting the devices formed according to the prior art.

### BRIEF SUMMARY OF THE INVENTION

The present disclosure relates to forming the active areas of the matrix of memory cells so that they are equidistant from each other and advantageously have the same dimensions.

In accordance with one embodiment of the invention, a non-volatile memory device integrated on a semiconductor substrate and including a matrix of non-volatile memory cells organized in rows, called wordlines, and columns, called bitlines, is provided. The device includes a plurality of active areas formed equidistant from each other on the semiconductor substrate having a first and a second group of active areas; said non-volatile memory cells integrated in said first group of active areas, each non-volatile memory cell including a source region, a drain region, and a floating gate electrode coupled to a control gate electrode, at least one group of the memory cells sharing a common source region integrated on the semiconductor substrate; and a contact region integrated in the second group of active areas and provided with at least one common source contact of the common source region.

In accordance with the foregoing embodiment, the active areas are ideally formed in the shape of strips parallel to each other and ideally have a same width. Also, in a preferred embodiment, pairs of active areas are short circuited by a portion of the semiconductor substrate that is formed therebetween.

In accordance with another embodiment, a method is provided for forming a non-volatile memory electronic device integrated on a semiconductor substrate. The method includes forming a dielectric layer and a protective layer on a semiconductor substrate; selectively removing the dielectric layer and the protective layer to form active areas; removing a portion of the semiconductor substrate using a same first photolithographic mask that was used to selectively remove the dielectric layer and the protective layer to thereby form trenches that separate different, non-removed regions of the nitride layer; oxidizing a surface of the exposed semiconductor substrate to fill the trenches in the semiconductor substrate with a dielectric layer; planarizing the dielectric layer surface by means of CMP technique for removing the dielectric layer formed above the protective layer; and removing the protective layer and an underlying oxide layer to uncover a surface of the active areas.

### BRIEF DESCRIPTION OF THE SEVERAL VIEWS OF THE DRAWINGS

The characteristics and the advantages of the device according to the disclosure herein will be apparent from the following description of an embodiment thereof given by way of indicative and non limiting example with reference to the annexed drawings.

In these drawings:

FIG. 1 shows a top schematic view of a portion of memory electronic device formed according to the prior art;

FIG. 2 shows a top schematic view of a portion of a first embodiment of the memory electronic device formed according to the disclosure;

FIG. 3 shows a top schematic view of a portion of a photolithographic mask used during a step of a process for manufacturing the memory electronic device of FIG. 2.

FIG. 4 shows a top schematic view of a portion of a first embodiment of the memory electronic device according to the disclosure;

FIG. 5 shows a top schematic view of a portion of a photolithographic mask used during a process for manufacturing the memory electronic device of FIG. 4.

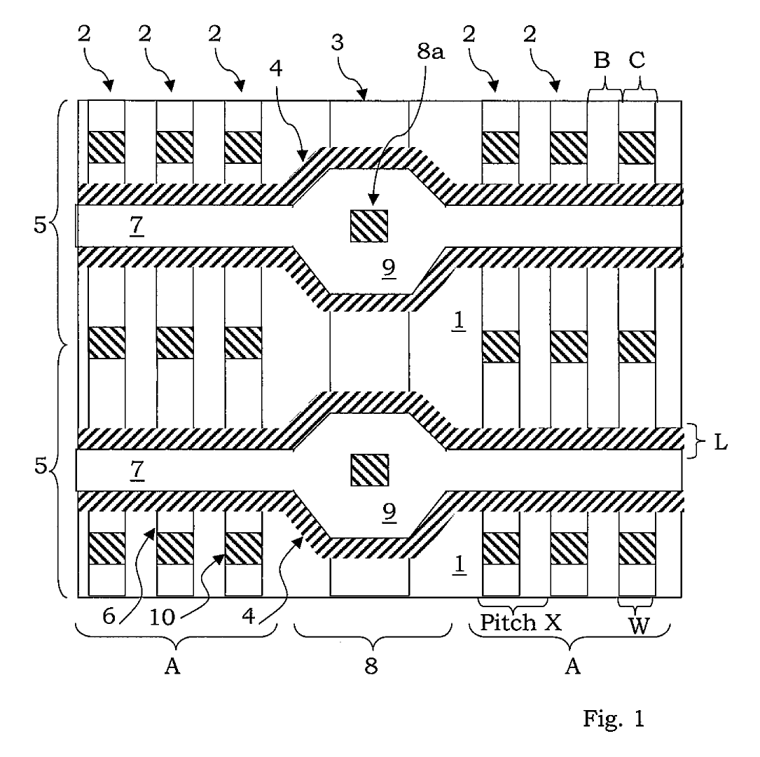

### DETAILED DESCRIPTION OF THE INVENTION

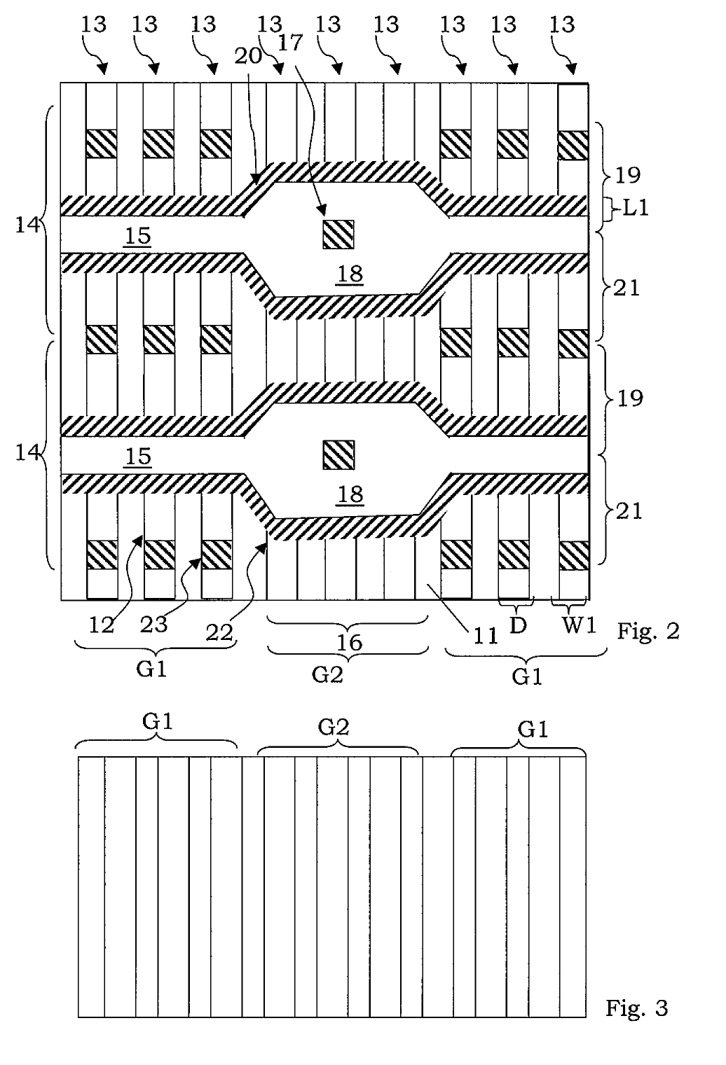

With reference to FIGS. 2 to 5, a non-volatile memory electronic device is described.

The process steps and the structures described hereafter do not form a complete process flow for the manufacturing of integrated circuits. The figures showing cross sections of portions of an integrated circuit during the manufacturing are not drawn to scale, but they are instead drawn so as to show the important characteristics of the invention.

The described embodiments can be put into practice together with the manufacturing techniques of integrated circuits currently used in the field, and only those commonly used process steps necessary for the comprehension of the present disclosure are included.

In particular, with reference to FIG. 2, a first embodiment is described of a non-volatile memory device integrated on a semiconductor substrate 11 and comprising a memory matrix formed by a plurality of non-volatile memory cells 12 that are organized in rows, called word lines, and columns, called bit lines. In particular, in the memory matrix a plurality of active areas 13 are formed on the semiconductor substrate 11.

Each active area 13 is at least partially surrounded by a dielectric layer called field oxide. These active areas 13 are equidistant from each other. For example, they are strips parallel to each other, and they have a same width D.

In a first group G1 of active areas 13, non-volatile memory cells 12 are formed, each non-volatile memory cell 12 having a source region, a drain region and a floating gate electrode coupled with a control gate electrode. A second group G2 of active areas 13 are integrated in a contact region 18.

In the device according to the present disclosure, at least one first group 14 of memory cells 12 shares a common source region 15 integrated on the semiconductor substrate 11.

In particular, pairs of cells 12 formed on the same active areas 13 and arranged symmetrically with respect to the common source region 15 share a same source region, the source regions of the memory cells 12 of the same group 14 of memory cells being electrically connected to one another by the common source region 15.

This common source region 15 is obtained, in a conventional way, by removing a portion of the oxide layer between adjacent active areas 13 and carrying out a dopant implantation in the semiconductor substrate 11. To avoid excessive resistance in the common source region 15, the matrix of cells is interrupted at regular intervals (each 16 cells, or each 32 cells) by inserting the contact region 16 at the interconnection with the common source region 15. Therefore, in the matrix of memory cells 13, first groups G1 of active areas and second groups G2 of active areas are alternated.

Advantageously, the contact region 16 is formed in correspondence with at least three adjacent active areas 13 inside the second group G2 of active areas. In fact, to locate a source contact 17 inside the contact region 16 without problems of electric interference, the common source region 15 will have to provide a pad 18 widened in correspondence with this contact region 16. In particular, the widened pad 18 has a polygonal shape which is distributed inside the contact region 16 and it is in electric contact with the three active areas inside the contact region 16.

Advantageously, the source contact 17 is formed in correspondence with the central active area inside the contact region 16, while the two adjacent active areas 13 only serve to maintain the regularity of the matrix.

In this embodiment of the device, the pitch of the memory matrix, i.e., the pitch X, can thus be maintained constant. Moreover, inside the first group 14 of memory cells a second and a third group of memory cells can be identified.

The second group 19 of memory cells arranged above the common source region 15 and formed in different active areas share a first word line 20. This word line 20, in particular, connects the control electrodes of the memory cells of the second group 19 of memory cells.

The third group 21 of memory cells, arranged below the common source region 15 and formed in different active areas, share a second word line 22. This word line 22, in particular, connects the control electrodes of the memory cells of the third group 21 of memory cells.

The word lines 20, 22 must thus provide a particular shaping, inside the contact region 16 to allow the insertion of the widened pad 18 and of the source contact 17.

As noted in fact with reference to the prior devices, memory devices of the NOR type with high density are generally projected with SAS architecture (Self Aligned Source) to reduce the dimension of the memory cell 12. Therefore the common source region 15 and the widened pad 18 are formed as self-aligned to the word lines 20, 22 and thus the word lines 20, 22 must be formed so as to follow the profile of the widened pad 9.

In a conventional way, after having formed drain regions of the memory cells 12 inside the active areas 13, drain contacts 23 are formed aligned to each other, while as already noted, the source contact 17 is formed inside the contact region 16, in particular in correspondence with the central active area and it is aligned to the common source region 15 along the first direction.

Clearly, the drain regions of the memory cells 12 are not formed in correspondence inside the active areas 13, which are comprised in the contact region 16.

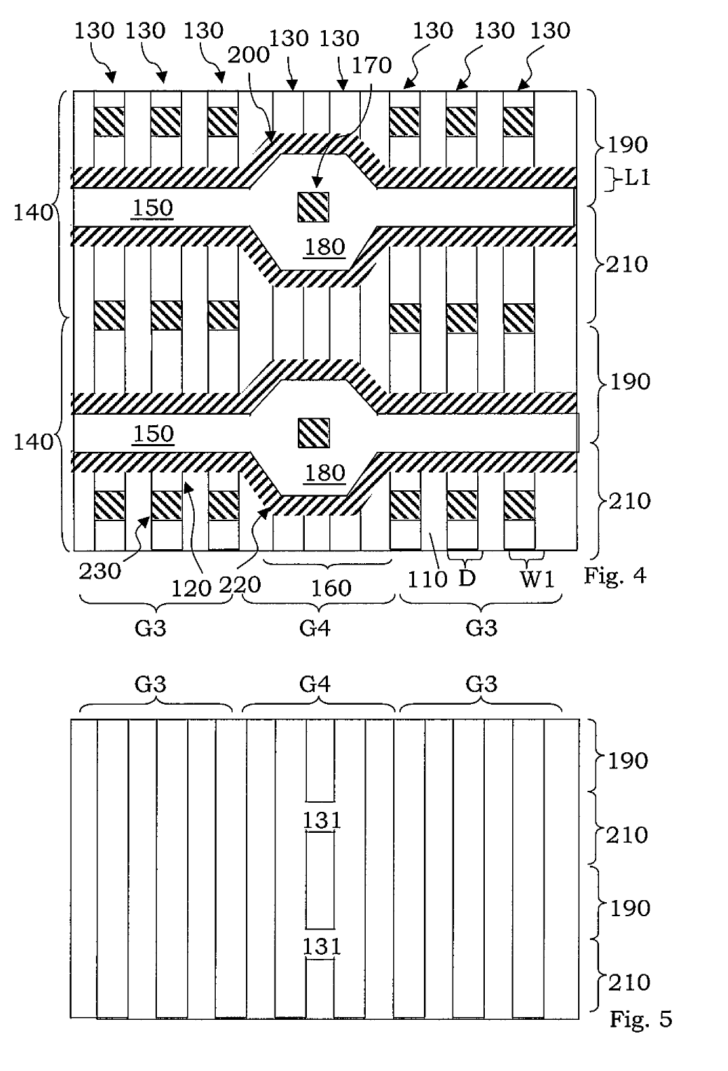

With reference to FIG. 4, a second embodiment of a non-volatile memory device integrated on a semiconductor substrate 10 is shown having a memory matrix formed by a plurality of non-volatile memory cells 120 organized in rows, called word lines, and columns, called bit lines. In particular, in the memory matrix a plurality of active areas 130 are formed on the semiconductor substrate 110.

Each active area 130 is at least partially surrounded by a dielectric layer called field oxide.

These active areas 130 are equidistant from each other. For example, they are strips parallel to each other extending in a first direction, and they have a same width D1.

In a first group G3 of active areas 130, non-volatile memory cells 120 are formed, each non-volatile memory cell 120 having a source region, a drain region, and a floating gate electrode coupled to a control gate electrode. In a second group G4 of active areas 130 a contact region 180 is integrated. Advantageously, according to this second embodiment of the non-volatile memory device, at least one pair of active areas of the second group G4 of active areas is short-circuited among them.

In a known way, these active areas 130 are formed by means of a photolithographic technique that provides the use of a photolithographic mask, for example as the one shown in FIG. 5.

In particular, at least between a pair of adjacent active areas 130 of the second group G4 of active areas, there is at least one conductive interconnection portion 131 so as to short-circuit them.

In particular, the conductive interconnection portion 131 is formed by a portion of semiconductor substrate 110 formed between at least the pair of active areas 130, wherein the field oxide layer has not been formed. A first group 140 of memory cells shares a common source region 150 integrated in the semiconductor substrate 110. In particular, the portion 131 of the semiconductor substrate 110 formed within this pair of cells 130 of the second group G4 of active areas is aligned to the common source region 150 along the first direction.

Moreover, pairs of cells 120 formed in the same active area 130 and arranged symmetrically with respect to the common source region 150 share a same source region, the source regions of the memory cells 120 of the first group 140 of memory cells being electrically connected to each other by the common source region 150. This common source region 150 is obtained, in a conventional way, by removing a portion of the oxide layer between adjacent active areas 13 and by carrying out a dopant implantation in the semiconductor substrate 11.

To avoid excessive resistance in the common source region 150, the matrix of cells is interrupted at regular intervals (each 16 cells, or each 32 cells) for inserting the contact region 160 at the interconnection with the common source region 150.

As already highlighted, this contact region 160 is formed in correspondence with the two adjacent active areas 130 short-circuited with each other. In fact, to allocate a source contact 170 inside the contact region 160 without electric interference problems, the common source region 150 will have to provide a pad 180 widened in correspondence with this contact region 160. In particular, the widened pad 180 has a polygonal shape that is distributed inside the contact region 160 and is in electric contact with the two active areas inside the contact region 16. The source contact 170 is then formed in correspondence with the portion 131 of the semiconductor substrate 110 formed within this pair of adjacent cells 130.

Moreover, inside the first group 140 of memory cells a second and a third group of memory cells can be identified.

The second group 190 of memory cells that are arranged above the common source region 150 and are formed in different active areas share a first word line 200. This word line 200, in particular, connects the control electrodes of the memory cells of the second group 190 of memory cells.

The third group 210 of memory cells that are arranged below the common source region 150 and are formed in different active areas share a second word line 220. This word line 220, in particular, connects the control electrodes of the memory cells of the third group 210 of memory cells. The word lines 200, 220 must be provided with a particular shaping, inside the contact region 160 to allow the insertion of the widened pad 180 and of the source contact 170.

As noted with reference to the prior devices, memory devices of the NOR type with high density are generally designed with SAS architecture (Self Aligned Source) to reduce the dimension of the memory cell 120. Therefore the source region 150 and the widened pad 180 are formed as self-aligned to the word lines 200, 220 and thus the word lines 200, 220 must be formed so as to follow the profile of the widened pad 90.

In a conventional way, after having formed drain regions of the memory cells 120 inside the active areas 130, drain contacts 230 are formed that are self-aligned, while said source contact 170 is formed in correspondence with portions 131 of the semiconductor substrate 110 formed within this pair of adjacent cells 130.

Clearly, the drain regions of the memory cells 120 are not formed inside the active areas 130 of the second group G4 of active areas. In this embodiment, the contact region 160 shows a double space with respect to the space of the single cell, i.e., the pitch X of the matrix.

Also in this embodiment, the matrix periodicity is substantially maintained, since the impact of the portions 131 that are used for allocating the source contact 170 is minimal.

A process is now described for manufacturing a non-volatile memory electronic device integrated on a semiconductor substrate 11, 110, for example of the P type. In a conventional way active areas 13, 130 of memory cells 12, 120 are formed by means of a process that includes the steps of:

forming, in cascade, a dielectric layer, for example of silicon oxide and a protective layer, for example of silicon nitride on the semiconductor substrate 11, 110,

selectively removing the layers of silicon nitride and silicon oxide by means of a photolithographic technique which provides the use of a first photolithographic mask, for forming active areas 13, 130 for the memory cells 120,

removing a part of semiconductor substrate using the same first photolithographic mask forming trenches that separate different, non removed regions of the nitride layer,

oxidizing the surface of the exposed semiconductor substrate and filling in the trenches in the semiconductor substrate with a dielectric layer, for example of field oxide,

planarizing the surface by means of CMP technique (chemical mechanical polishing) for removing the dielectric layer formed above the silicon nitride layer, and

removing the silicon nitride layer and the underlying oxide layer for uncovering the surface of the active areas 13, 130 for the memory cells 12, 120.

For example, a photolithographic mask used to form the active areas 13 of the first embodiment of the device is shown in FIG. 3, while a photolithographic mask used to form active areas 130 of the second embodiment of the device is shown in FIG. 5. Ideally, these active areas 13, 130 are equidistant from each other.

Advantageously, these active areas 13, 130 are strips being parallel to each other and extending in a first direction, being equidistant and having a same width D.

In a first group G1, G3 of the active areas 13, 130, the non-volatile memory cells 12, 120 will be integrated, in a second group G2, G4 of the active areas 13, 130 a contact region 180, 180 is integrated.

In the first embodiment of the device the second group G2 of active areas comprises at least three adjacent active areas.

In the second embodiment of the device the second group G4 of active areas includes at least one pair of adjacent active areas short-circuited with each other. In particular, in at least one interconnection portion 131 of the semiconductor substrate 110, which contacts this pair of active areas, the field oxide layer that insulates the active areas from each other is not formed, therefore the interconnection portion 131 short-circuits the pair of active areas it is in contact with.

In sequence on the whole semiconductor substrate 11, 11, at least a first dielectric layer, for example of active oxide also known as tunnel oxide and a first conductive layer, for example of polysilicon, are then formed. The first conductive layer is etched by means of a second mask to defined floating gate electrodes of the memory cells 12, 120 of width W1 along a first direction, which are formed in the first group G1, G3 of active areas. For example, this second mask has openings of greater dimensions with respect to the first mask, so the width W1 of the memory cells is greater e than the width D of the active areas.

Nothing prevents other process steps from being carried out to form the floating gate electrodes of the memory cells.

In sequence on the whole semiconductor substrate 11, 110, at least one second dielectric layer, for example interpoly oxide, a second conductive layer, for example of polysilicon, and a third photolithographic mask, are then formed to define gate electrodes of the memory cells 12 in a second direction perpendicular to the first direction.

The second conductive layer, the second dielectric layer, the first conductive layer and the first dielectric layer are then etched in sequence through the third mask until the semiconductor substrate is exposed and the gate electrodes of the memory cells having a length L1 are completed.

In particular, with this latter etching step, in the second conductive layer the word lines 20, 21; 200, 210 of the matrix of memory cells 12, 120 are defined. The portions of word lines 20, 21; 200, 210 aligned to the floating gate electrodes form control gate electrodes of the single memory cells 12, 120. In particular the word lines 20, 21; 200, 210 extend in a direction perpendicular to the first direction in correspondence with the active areas of the first Group G1, G3 of the active areas and they are spaced from each other in correspondence with the active areas of the second Group G2, G4 of the active areas.

From the semiconductor substrate 11, 110 portions of the insulating layer are removed, being formed between portions of the semiconductor substrate 11, 110, wherein the source regions of the memory cells 12, 120 formed in adjacent active areas will be formed. A common source region 15, 150 is then formed, for example of the N type, which is shared by first groups 14, 140 of the memory cells 12, 120. Pairs of cells 12, 120 formed in the same active area 13, 130 and placed symmetrically with respect to the common source region 15, 150 share a same source region, and the source regions of the memory cells 12 of the same first group 14 of memory cells are electrically connected to each other by the common source region 15, 150.

The common source region 15, 50 is also formed by a pad 18, 180 widened in correspondence with this contact region 16, 160 which is self-aligned to the word lines 20, 21; 200, 210.

In particular, the widened pad 18, 180 has a polygonal shape that is distributed inside the contact region 16, 160, and it is in electric contact with active areas inside the contact region 16.

After having formed the drain regions in the memory cells 12, 120, and a premetal dielectric layer, openings are formed in correspondence with the drain regions of the memory cells 12, 120 for forming drain contacts 23, 230. The source contact 17 is then formed inside the contact region 160 and it is aligned to the common source region 15.

In conclusion, the device is provided with a contact region 16, 160 that maintains the pitch of the matrix masks uniform without requiring a reduction of the minimal dimensions for each single masking level. Therefore, the contact region 16, 160 shows a space exactly identical to an integer multiple of the dimension of the matrix cell, i.e., of the pitch X.

Moreover, the formation of active areas being equidistant and having identical dimensions simplifies the lithographic definition of the critical masks for forming the memory matrix in correspondence with the contact region, modifying only the interconnection structure without addition of specific process steps and without addition of complexity in the creation of the masks.

The structure here described can be applied to memories with a common source region of the EPROM, Flash EEPROM type with NOR organization, with single or multi level.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A non-volatile memory device integrated on semiconductor substrate and including a matrix of non-volatile memory cells organized in rows, called word lines, and columns, called bit lines, the device comprising:
a plurality of active areas formed on the semiconductor substrate comprising a first and a second group of active areas;
said non-volatile memory cells integrated in said first group of active areas, each non-volatile memory cell comprising a source region, a drain region, and a floating gate electrode coupled to a control gate electrode, at least one group of said memory cells sharing a common source region integrated on said semiconductor substrate;
said plurality of active areas are formed equidistant from each other; and
a contact region integrated in said second group of active areas and provided with at least one common source contact of said common source region.

2. The non-volatile memory device of claim 1 wherein said active areas are strips parallel to each other and have a same width.

3. The non-volatile memory device of claim 1 wherein pairs of cells formed in the same active area and arranged symmetrically with respect to the common source region share a same source region, the source regions of the memory cells of said at least one group of memory cells electrically connected to each other by the common source region.

4. The non-volatile memory device of claim 1 wherein said common source region comprises a widened pad in correspondence with the contact region.

5. The non-volatile memory device of claim 1 wherein said widened pad has the polygonal shape that is distributed inside the contact region and is in electric contact with said active areas of said second group of active areas.

6. The non-volatile memory device of claim 1 wherein the contact region is in correspondence with at least three adjacent active areas of said second group of the active areas.

7. The non-volatile memory device of claim 1 wherein said source contact is then in correspondence with the central active area formed inside the contact region.

8. The non-volatile memory device of claim 1 wherein said contact region is in correspondence with at least one pair of active areas of the second group of the active areas.

9. The non-volatile memory device of claim 8 wherein said pair of active areas is short-circuited by a portion of said semiconductor substrate that is formed there between.

10. The non-volatile memory device of claim 9 wherein said source contact is in correspondence with said portion of said semiconductor substrate formed between said pair of adjacent cells.

11. A circuit, comprising:
a plurality of active areas formed on a semiconductor substrate to be spaced equidistant from each other, the plurality of active areas comprising a first group and a second group of active areas, a plurality of non-volatile memory cells integrated in the first group of active areas and comprising at least one group of memory cells sharing a common source region integrated on the semiconductor substrate, and a contact region integrated in the second group of active areas that is provided with at least one common source contact for the common source region.

12. The circuit of claim 11 wherein the active areas in the first group of active areas comprise strips formed parallel to each other and formed to have a same width.

13. The circuit of claim 12, comprising pairs of memory cells formed in each active area and arranged symmetrically with respect to the common source region and sharing the same source region, with source regions of the pairs of memory cells in the first group of active areas electrically connected to each other by the common source region.

14. The circuit of claim 13 wherein the common source region comprises a widened pad formed in correspondence with the contact region.

15. The circuit of claim 14 wherein the pair of active areas are short circuited by a portion of the semiconductor substrate that is formed therebetween.

16. A process for manufacturing a circuit, comprising:
forming a dielectric layer and a protective layer on a semiconductor substrate;
selectively removing the dielectric layer and the protective layer to form active areas;
removing a portion of the semiconductor substrate using a same photolithographic mask that was used to selectively remove the dielectric layer and the protective layer to thereby form trenches that separate different, non-removed regions of the nitride layer;
oxidizing a surface of the exposed semiconductor substrate to fill in the trenches in the semiconductor substrate with a dielectric layer;
planarizing the dielectric layer surface by means of CMP technique to remove the dielectric layer formed above the protective layer; and
removing the protective layer to uncover a surface of the active areas.

17. The process of claim 16 wherein the dielectric layer comprises silicon oxide and the protective layer comprises silicon nitride.

18. The process of claim 16 wherein the dielectric layer that fills the trenches in the semiconductor substrate and the exposed surface of the semiconductor substrate comprises a field oxide.

19. The process of claim 18 wherein the active areas are formed to have a same width and are equidistant from each other.

20. The process of claim 19 wherein the active areas comprise strips that are formed parallel to each other.
